(19) United States
(12) Patent Application Publication
(10) Pub. No.: US 2015/0292815 A1
(43) Pub. Date: Oct. 15, 2015

(54) SUSCEPTOR WITH RADIATION SOURCE COMPENSATION

(71) Applicant: APPLIED MATERIALS, INC., Santa Clara, CA (US)

(72) Inventor: Joseph M. RANISH, San Jose, CA (US)

(73) Assignee: APPLIED MATERIALS, INC., Santa Clara, CA (US)

(21) Appl. No.: 14/294,867

(22) Filed: Jun. 3, 2014

Related U.S. Application Data
(60) Provisional application No. 61/977,952, filed on Apr. 10, 2014.

(51) Int. Cl. F28F 3/00; F28F 21/08; C23C 14/22; C23C 16/458; C23C 16/40; F28F 21/02; C30B 25/12

(52) U.S. Cl. CPC F28F 3/00; F28F 21/02; F28F 21/084; C30B 25/12; C23C 16/458; C23C 16/402; C23C 14/22

(57) ABSTRACT

Embodiments described herein relate to an apparatus and methods for temperature measurement. A susceptor may be configured to support a substrate on a first surface and second surface of the substrate may be oriented opposite the first surface. One or more reflective features may be formed on the second surface. The one or more reflective features may be disposed in various patterns at a radius viewed by a temperature sensor. The one or more reflective features may provide for increased reflection of radiation from the second surface of the susceptor and provide more accurate temperature calculations from a thermal signal detected by the temperature sensor.

### CROSS-REFERENCE TO RELATED APPLICATIONS

This application claims benefit of U.S. provisional patent application No. 61/977,952, filed Apr. 10, 2014, which is hereby incorporated by reference.

### BACKGROUND

1. Field

Embodiments described herein generally relate apparatus and methods of temperature metrology. More specifically, embodiments described herein relate to measuring temperature of a susceptor exposed to a radiation source.

2. Description of the Related Art

Accurate temperature metrology in certain semiconductor processing chambers is important for processing of a substrate. For example, in an epitaxial deposition chamber, heat sources providing radiant energy may be utilized to heat a substrate disposed on a susceptor. Radiation pyrometry may be utilized to measure the thermal signature of a bottom surface of the susceptor as the bottom surface generally exhibits a generally constant emissivity. The thermal signature may be detected by pyrometers and a temperature of the susceptor may be calculated from the thermal signature.

However, radiation may reflect off of the susceptor into the pryrometer and artificially augment the thermal signature detected by the pyrometer. The artificial augmentation may lead to inaccurate temperature calculation of the susceptor. One technique to estimate and compensate for the reflected radiation augmentation relies on measuring contributions to the pyrometer signal from the radiation source when the susceptor is cold, generating a lookup table from the data, and estimating the net contribution of the reflected radiation using the lookup table. However, inaccuracies arise from the effects of radiation source ageing, radiation source replacement, susceptor replacement, and process drift more generally.

Thus, what is needed in the art are apparatus and methods for providing improved temperature measurement and compensation calculations for reflected radiation.

### SUMMARY

In one embodiment, an apparatus for processing a substrate is provided. The apparatus comprises a susceptor having a first substrate supporting surface and a second surface oriented opposite the first surface. One or more reflective feature may be formed on the second surface in an annular pattern. The one or more reflective features may be more reflective than the second surface of the susceptor.

In another embodiment, an apparatus for processing a substrate is provided. The apparatus comprises a process chamber having a processing volume and a susceptor disposed in the processing volume. The susceptor may have a first substrate supporting surface and a second surface oriented opposite the first surface. One or more reflective features may be formed on the second surface in an annular pattern. The one or more reflective features may be more reflective than the second surface of the susceptor. A plurality of radiant energy source may be coupled to the chamber below the second surface and a temperature sensor may be oriented to detect electromagnetic radiation from a desired radius of the second surface.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a bottom view of a susceptor according to a first embodiment described herein.

FIG. 1B illustrates a cross-sectional view of the susceptor of FIG. 1A along section line 1B-1B.

FIG. 1C illustrates a bottom view of a susceptor according to a second embodiment described herein.

FIG. 1 D illustrates a cross-sectional view of the susceptor of FIG. 1C along section line 1C-1C.

FIG. 2A illustrates a bottom view of a susceptor according to a third embodiment described herein.

FIG. 2B illustrates a cross-sectional view of the susceptor of FIG. 2A along section line 2B-2B.

FIG. 3 illustrates a schematic, side view of a processing chamber according to one embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein relate to an apparatus and methods for temperature measurement. A susceptor may be configured to support a substrate on a first surface and a second surface of the substrate may be oriented opposite the first surface. One or more reflective features may be formed on the second surface. The one or more reflective features may be disposed in various patterns at a radius viewed by a temperature sensor. The one or more reflective features may provide for increased reflection of radiation from the second surface of the susceptor and enable more accurate temperature calculations from a thermal signal detected by the temperature sensor.

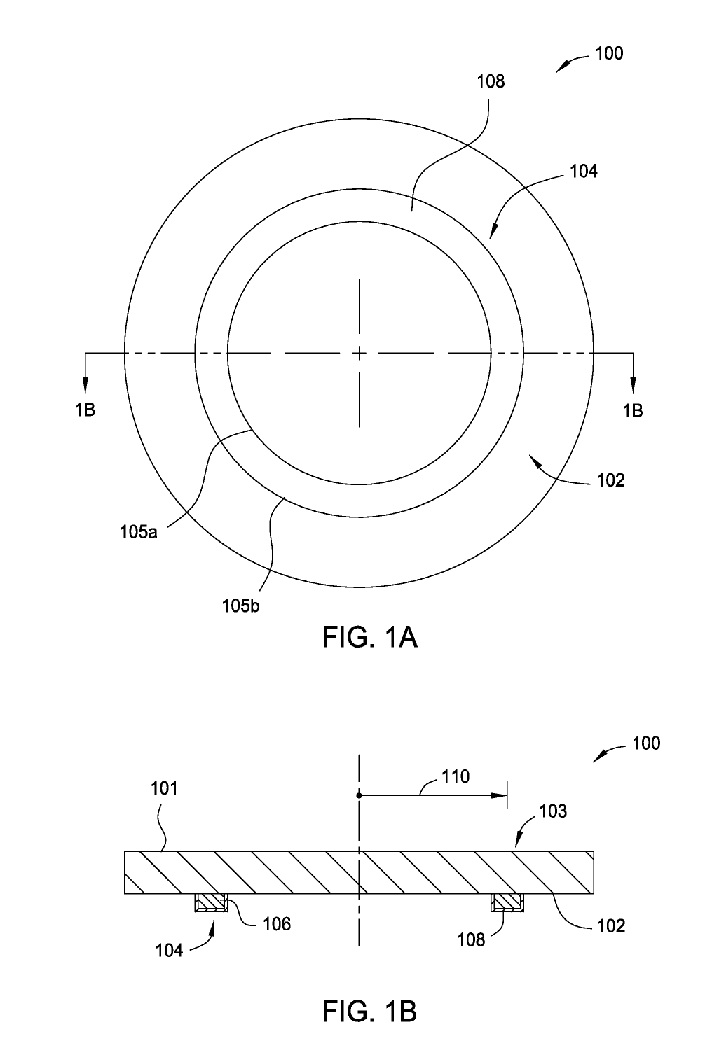

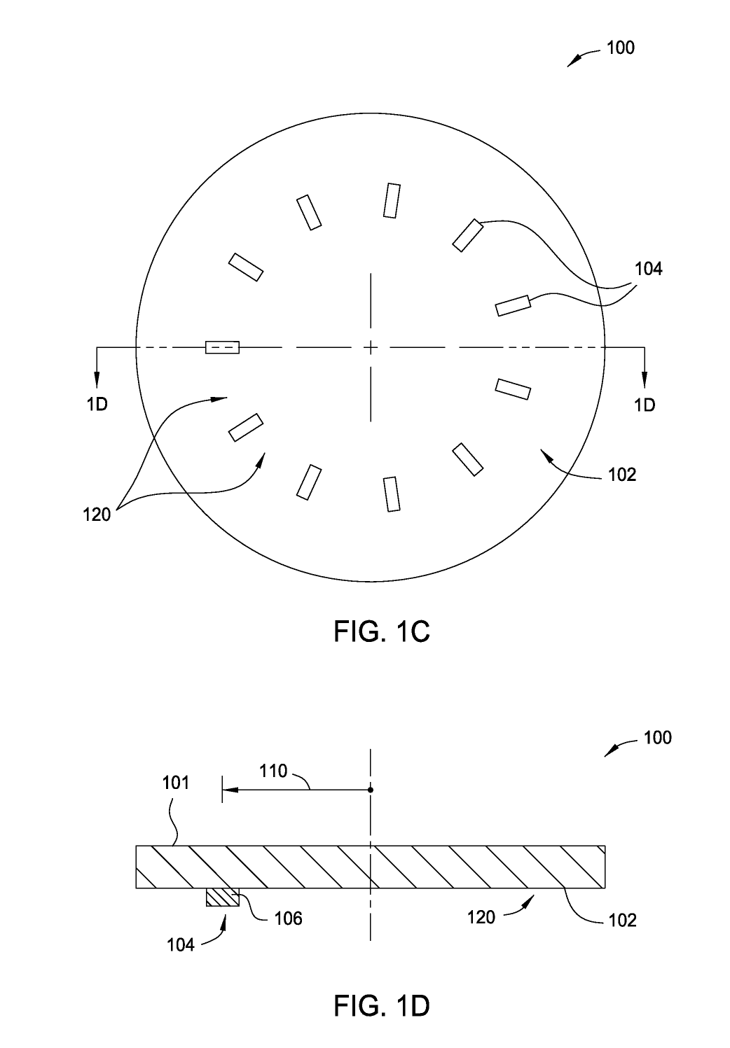

FIG. 1 illustrates a bottom view of a susceptor 100 according to one embodiment described herein. The susceptor 100 may be fabricated from any process compatible material, such as monolithic silicon carbide (SiC), monolithic graphite, or graphite coated with SiC. In embodiments comprising monolithic SiC, the susceptor 100 may be sintered from SiC powder to a net shape (e.g., a final shape), or near net shape and then processed further to a net shape. The susceptor 100 may be formed from graphite by sintering as above, or by machining from a block of graphite material. A graphite susceptor may also be coated with a SiC coating using any suitable method to coat the desired surface.

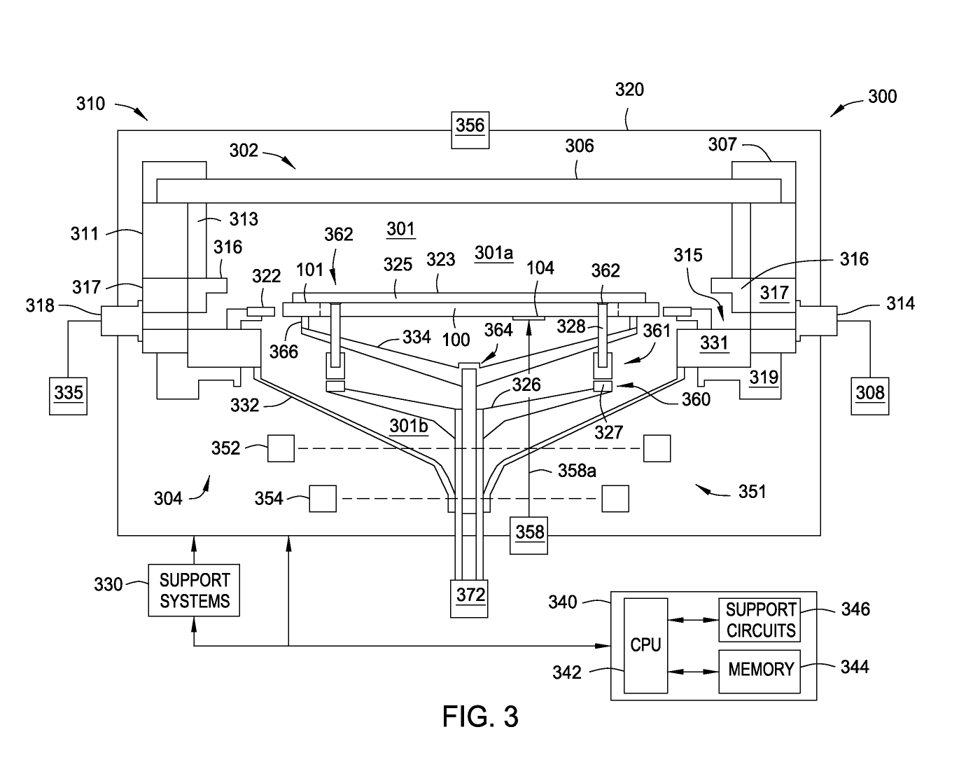

The susceptor 100 has a first surface 101 (shown in FIG. 1B) comprising a substrate support surface 103 (shown in FIG. 1B) configured to support a substrate (such as substrate 325 depicted in FIG. 3) during processing. The susceptor 100 has a second surface 102, opposing the first surface 101, including one or more features 104. The features 104 may be of any shape or pattern. For example, the feature 104 may compromise a single annulus bounded by an outer curved edge 105a and an inner curved edge 105b as illustrated in FIG. 1. It is contemplated that more than one annulus may be utilized. Other shapes may also be beneficial in certain embodiments. For example, an elliptical feature shape may be utilized.

FIG. 1B illustrates a cross-sectional view of the susceptor 100 of FIG. 1A along section line 1B-1B. In one embodiment, the features 104 extend from the second surface 102. For example, the features 104 may have a thickness of between about 1 Å and about 1 mm, depending on the desired reflective and thermal characteristics desired. Alternatively, the features 104 may be formed in the second surface 102 such that the features 104 and the second surface 102 are co-planar. The features 104 may be disposed at a first radius 110 on the second surface 102 of the susceptor 100. The radius may be selected to match a region of the second surface 102 viewed by a temperature sensor (See FIG. 3; pyrometer 358).

The features 104 may be formed on the susceptor 100 in any suitable fashion, such as being cast in the susceptor 100, embossed into the susceptor 100, machined into the susceptor 100, deposited on the susceptor 100, or by roughening or treating the second surface 102 of the susceptor 100. For example, the features 104 may be conformally deposited on the second surface 102 by a physical vapor deposition (PVD) process or other similar conformal deposition process. The conformal deposition of the features 104 enables the features 104 to retain a surface roughness similar to the surface roughness of the second surface 102. By matching the surface roughness of the second surface 102 and the surface roughness of the features 104, it may be possible to minimize differences in the amount of radiation reflected from the second surface 102 and the features 104.

The features 104 may be formed from a material 106 that exhibits reflective characteristics and is thermally stable at processing temperatures between about 300 and about 900 degrees Celsius. The material 106 selected for the features 104 may include aluminum, platinum, iridium, rhenium, and gold, among others. If the material selected for the features 104 has a melting point below the range of processing temperatures, a protective coating 108 (See FIG. 1B) may be formed over the features 104 to prevent the features 104 from deforming during processing. The protective coating 108 may also be conformally deposited over the material 106 to maintain the desired amount of surface roughness. In one embodiment, the material 106 may be aluminum and the protective coating 108 may be silicon dioxide. The material 106 and protective coating 108 may be configured to be highly reflective and/or may be selective to wavelengths within a desired range. The material 106 may also be selected to have a similar absorptivity as the second surface 102 to mitigate temperature differences between the features 104 and the second surface 102.

FIG. 1C illustrates a bottom view of the susceptor 100 according to one embodiment described herein. The features 104 need not be a continuous structure as illustrated in FIG. 1A. For example, the features 104 may comprise a plurality of discrete structures disposed on the second surface 102 in a spaced apart fashion. If the features 104 are discrete, a shape of the features 104 may exhibit a high aspect ratio which may be perpendicular to a rotational patch of the susceptor 100. The shape of the features 104 may be configured to minimize thermal gradients between the features 104 and the second surface 102. Regions 120 of the second surface 102 between the features 104 may comprise only the material of the susceptor 100 or may be coated with a reflective or absorptive material. In one embodiment, the regions 120 may be coated with a broadband reflector which is selected to absorb and/or reflect radiation at desired wavelengths. As such, radiation reflected from the features 104 is more easily detected to measure the actual contribution of reflected radiation at a certain wavelength.

In one embodiment, the features 104 may be spaced apart along the first radius 110 to provide for azimuthal variation between the discrete features 104. The azimuthal variation may be constant or exhibit periodic differences between adjacent features. The spacing between adjacent features 104 may be of a spatial extent small enough to be compensated for by the thermal diffusion length of the susceptor material. As such, the shapes and spacing of the features 104 may be configured to minimize thermal gradients between the features 104 and the second surface 102.

FIG. 1D illustrates a cross-sectional view of the susceptor 100 of FIG. 1C along section line 1C-1C. Similar to FIG. 1B, the features 104 may be disposed at the first radius 110 on the second surface 102 of the susceptor 100. As illustrated, the regions 120 may also be within the first radius 110 and both the features 104 and the regions 120 may be viewed by the temperature sensors. As illustrated, the feature 104 comprises the material 106 without the protective coating 108. In this example, the material 106, such as platinum, may be thermally stable at temperatures above about 900 degrees Celsius.

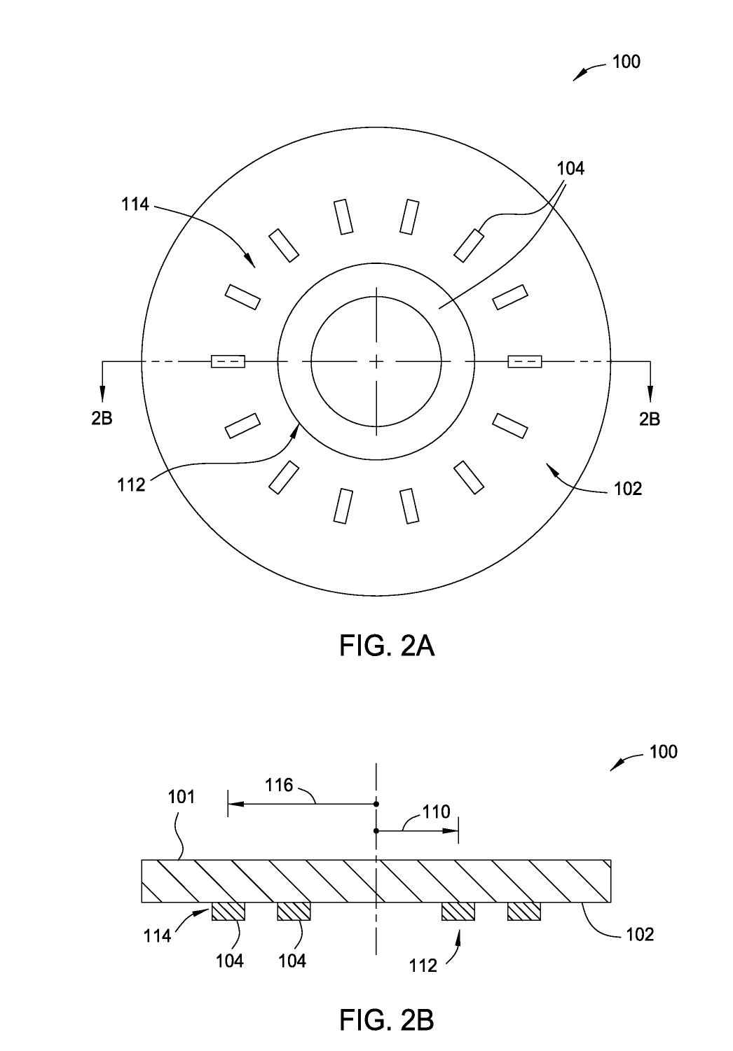

FIG. 2A illustrates a bottom view of the susceptor 100 according to one embodiment described herein. As depicted, a first feature pattern 112 and a second features pattern 114 are formed on the susceptor 100. The first feature pattern 112 may be similar to the feature 104 of FIG. 1A and the second feature pattern 114 may be similar to the feature 104 of FIG. 1C. It is contemplated that various feature patterns may be utilized in combination with one another in any arrangement on the second surface 102 to enhance the reflection of incident radiation on the features 104.

FIG. 2B illustrates a cross-sectional view of the susceptor 100 of FIG. 2A along section line 2B-2B. The first feature pattern 112 may be disposed on the second surface 102 at or near the first radius 110 and the second feature pattern 114 may be disposed on the second surface 102 at or near a second radius 116. In one embodiment, the first radius 110 and the second radius 116 are different. The radii 110, 116 may be selected to correspond to regions viewed by the temperature sensors.

In general, the features 104 are configured to have enhanced electromagnetic radiation reflection characteristics as compared to the second surface 102 of the susceptor 100. In certain embodiments, the entire second surface 102, or most of the second surface 102, may include the features 104. Alternatively, the features 104 may be disposed on regions of the second surface 102 viewed by the temperature sensors. The enhanced reflection of the features 104 may be limited to a wavelength or range of wavelengths. For example, the features 104 may have enhanced radiation reflection over a range of between about 0.4 micrometers to about 4.0 micrometers, or over a range of between about 3.0 micrometers to about 3.6 micrometers. In one embodiment, the features 104 have enhanced radiation reflection over a range centered about an operational wavelength of a pyrometer used to detect the temperature of the susceptor 100.

By enhancing the reflectivity of incident radiation on the second surface 102, the features 104 enable the temperature sensors to more accurately determine the contribution of the reflected radiation in the thermal signature of the susceptor 100. Although the enhanced reflectivity may further distort the thermal signature from the actual temperature of the susceptor 100, the contribution of the reflected radiation may be calculated in real time by collecting all or most of the reflected radiation. The ability to monitor the reflected radiation in the thermal signature provides for improved data when calculating the contribution of the reflected radiation in the overall thermal signature. Thus, the thermal signature of the susceptor 100 may be more accurately analyzed because the contribution of the reflected radiation is known and the reflected radiation's contribution may be accounted for in determining the temperature of the susceptor 100.

FIG. 3 illustrates a schematic, side view of a processing system 300 comprising a processing chamber 310 according to one embodiment described herein. The processing chamber 310 may be a commercially available processing chamber, such as the RP EPI® reactor, available from Applied Materials, Inc., of Santa Clara, Calif. Other similarly configured processing chambers from other manufacturers adapted for performing epitaxial silicon deposition processes or chemical vapor deposition (CVD) processes may also benefit from the embodiments described herein.

The processing system 300 may be configured to perform epitaxial deposition processes. The system 300 comprises the process chamber 310, a processing volume 301, a gas inlet port 314, an exhaust manifold 318, and the susceptor 100. The susceptor 100 separates the processing volume 301 into an first volume 301a above the first surface 101 and a second volume 301b below the first surface 101. The processing system 300 may also include a controller 340, as discussed in greater detail below.

The gas inlet port 314 may be disposed at a first side of the susceptor 100 (e.g. in the first processing volume 301a) disposed inside the processing chamber 310 to provide a process gas across a processing surface 323 of a substrate 325 when the substrate 325 is disposed on the susceptor 100. One or more process gases may be provided from a gas panel 308 via the gas inlet port 314. The gas inlet port 314 may be fluidly coupled to a plenum space 315, which may be formed by one or more chamber liners of the first volume 301a to provide the process gas across the processing surface 323 of the substrate 325.

The exhaust manifold 318 may be disposed at a second side of the susceptor 100, opposite the gas inlet port 314, to exhaust the process gases from the chamber 310. The exhaust manifold 318 may include an opening that is about the same width, or slightly larger, than the diameter of the substrate 325. The exhaust manifold 318 may be heated, for example, to reduce deposition of materials on surface of the exhaust manifold 318. The exhaust manifold 318 may be coupled to a vacuum apparatus 335, such as a vacuum pump or the like, to exhaust process gases exiting the chamber 310.

The process chamber 310 generally includes an upper portion 302, a lower portion 304, and an enclosure 320. The upper portion 302 is disposed on the lower portion 304 and includes a chamber lid 306, an upper chamber liner 316, and a spacer liner 313. In certain embodiments, a first temperature sensor, such as a pyrometer 356, may be provided to collect and analyze data regarding the temperature of the processing surface 323 of the substrate 325 during processing. A clamp ring 307 may be disposed atop the chamber lid 306 to secure the chamber lid 306. The chamber lid 306 may have any suitable geometry, such as flat (as illustrated) or having a dome-like shape, among others. The chamber lid 306 may comprise a transparent material, such as quartz.

The spacer liner 313 may be disposed above the upper chamber liner 316 and below the chamber lid 306 as depicted in FIG. 3. The spacer liner 313 may be disposed on an inner surface of a spacer ring 311, where the spacer ring 311 is disposed in the process chamber 310 between the chamber lid 306 and a portion 317 of the process chamber 310 coupled to the gas inlet port 314 and the exhaust manifold 318. The spacer ring 311 may be removable and/or interchangeable with existing chamber hardware. In one embodiment, the spacer liner 313 may comprise quartz or the like.

As depicted in FIG. 3, the upper chamber liner 316 may be disposed above the gas inlet port 314 and the exhaust manifold 318 and below the chamber lid 306. In one embodiment, the upper chamber liner 316 may comprises quartz or the like. The upper chamber liner 316, the chamber lid 306, and a lower chamber liner 331 (discussed below) may be quartz, thereby advantageously providing a quartz envelope surrounding the substrate 325.

The lower portion 304 generally comprises a base plate assembly 319, a lower chamber liner 331, a lower dome 332, a susceptor 100, a pre-heat ring 322, a susceptor lift assembly 360, a susceptor support assembly 364, a heating system 351, and a second pyrometer 358. The heating system 351 may be disposed below the susceptor 100 to provide heat energy to the susceptor 100 as illustrated in FIG. 3. The heating system 351 may comprise one or more outer lamps 352 and one or more inner lamps 354. The one or more lamps 352, 354 may include an optional shield (not shown) to direct heat energy to a portion of the susceptor 100 and to prevent direct irradiation of the second pyrometer 358.

The second pyrometer 358 may be directed to a particular portion of the second surface 102 of the susceptor 100 as illustrated by the arrow 358a. The second pyrometer 358 may be directed to the feature 104 on the second surface 102 of the susceptor 100. Only one lower pyrometer is illustrated in FIG. 3, although it is contemplated that other pyrometers could be employed in certain embodiments and each pyrometer may be directed to a feature on the second surface 102 of the susceptor 100.

The second pyrometer 358 detects thermal radiation emitted by the targeted portion of the susceptor 100, in this case, feature 104. The second pyrometer 358 is configured to detect a particular wavelength, or range of wavelengths, of thermal radiation (e.g., the operational wavelength or wavelengths of the pyrometer). For example, in some embodiments, the second pyrometer 358 detects thermal radiation at wavelengths from about 1.0 to about 4.0 micrometers, for example from about 3.0 micrometers to about 3.6 micrometers, although other wavelengths may be used.

It has been observed that lamps typically used to provide heat in the form of IR radiation may produce radiation at a wavelength that overlaps the wavelength detected by the pyrometers 356, 358. For example, some lamps 352, 354 produce radiant energy in the form of IR radiation at a frequency range of about 0.4 micrometers to 4.0 micrometers. Some of the IR radiation emitted by the lamps 352, 354 may not absorbed by the susceptor 100. Instead, some of the IR radiation is reflected off of the susceptor 100 and some of the reflected radiation may be directed to the second pyrometer 358.

Reflected radiation may be received by the second pyrometer 358 in addition to the thermal signal emitted by the susceptor 100. In some cases, the reflected radiation interferes with the second pyrometer 358 detecting the desired thermal signal emitted by the susceptor 100. By enhancing the amount of lamp radiation reflected by the susceptor 100 and detected by the second pyrometer 358 enables enhanced compensation calculations when determining the reflected radiation contribution to the thermal signal emitted by the susceptor 100. Thus, the features 104, having a minimal emissivity difference relative to thermal conductance, provide for a more accurate determination of the reflected radiation to allow for compensation when determining the thermal signature of the susceptor 100 detected by the second pyrometer 358. In one embodiment, look up tables with known variables may be improved by more accurately sensing the reflected radiation.

The features 104 on the susceptor 100 increase the reflection of the incident thermal radiation provided by the heating system 351, thereby enhancing the emissivity of at least a portion of the susceptor 100. As used herein, the term “incident” refers to radiation arriving at or striking a surface. In some embodiments, the features 104 are configured to have enhanced reflectance of incident radiant energy at the wavelength, or range of wavelengths, produced by the lamps 352, 354. By enhancing the reflectance of all wavelengths of incident radiation from the lamps 352, 354, the features 104 provide a more accurate contribution of the reflected radiation detected by the second pyrometer 358, beneficially affecting the accuracy of the pyrometer readings. Increased reflectance of all wavelengths of incident radiant energy also has the benefit of increasing the accuracy of the source radiation contribution to allow for compensation in the pyrometer measurements.

Alternatively, the features 104 may be configured to enhance the reflectance of incident radiation at the wavelength, or range of wavelengths, detected by the pyrometer 358. For example, in some embodiments, the features 104 may be configured to have greater reflectance of incident radiation at wavelengths from about 1.0 micrometer to about 4.0 micrometers, for example about 3.0 micrometers to about 3.6 micrometers, than the second surface 102 of the susceptor 100 without the features 104. Such a scheme would reduce, or eliminate, inaccurate source radiation contribution detected by the pyrometer 358, thus increasing the accuracy of the compensation calculation of the thermal signal detected by the second pyrometer 358.

The features 104 may be formed on at least a portion of the susceptor 100, for example the portion of the susceptor 100 viewed by the second pyrometer 358. By providing the features 104 on the portion of the susceptor 100 viewed by the pyrometer 358, reflection of the specific pyrometer wavelength, or range of wavelengths, detected by the pyrometer 358 is enhanced to aid in the accurate calculation of the reflected radiation. Thus the accuracy and repeatability of the pyrometer readings is improved when the contribution of the reflected radiation is accurately determined.

In some embodiments, the portion of the susceptor 100 viewed by the second pyrometer 358 may comprise the features 104 alone, or may include the features 104 as well as an adjacent portion or portions of the second surface 102 without the features 104. In some embodiments, the features 104 may be formed on any portion, or portions, of a structure, for example the susceptor 100, or on any portion, or portions, of a surface of a structure, for example, the second surface 102.

The susceptor 100 may include any suitable substrate support surface 103, such as a plate (illustrated in FIG. 3) or ring (illustrated by dotted lines in FIG. 3) to support the substrate 325 thereon. The susceptor support assembly 364 generally includes a support bracket 334 having a plurality of support pins 366 to couple the support bracket 334 to the susceptor 100. The susceptor lift assembly 360 comprises a susceptor lift shaft 326 and a plurality of lift pin modules 361 selectively resting on respective pads 327 of the susceptor lift shaft 326. In one embodiment, a lift pin module 361 comprises an optional upper portion of the lift pin 328 that is movably disposed through a first opening 362 in the susceptor 100. In operation, the susceptor lift shaft 326 is moved to engage the lift pins 328. When engaged, the lift pins 328 may raise the substrate 325 above the susceptor 100 or lower the substrate 325 onto the susceptor 100.

The susceptor 100 may further include a lift mechanism 372 coupled to the susceptor support assembly 364. The lift mechanism 372 can be utilized to move the susceptor 100 in a direction perpendicular to the processing surface 323 of the substrate 325. For example, the lift mechanism 372 may be used to position the susceptor 100 relative to the gas inlet port 314. In operation, the lift mechanism may facilitate dynamic control of the position of the substrate 325 with respect to the flow field created by the gas inlet port 314. Dynamic control of the substrate 325 position may be used to optimize exposure of the processing surface 323 of the substrate 325 to the flow field to optimize deposition uniformity and/or composition and minimize residue formation on the processing surface 323. In some embodiments, the lift mechanism 372 may be configured to rotate the susceptor 100 about a central axis of the susceptor 100. Alternatively, a separate rotation mechanism may be provided.

During processing, the substrate 325 is disposed on the susceptor 100. The lamps 352, 354 are sources of infrared (IR) radiation (i.e., heat) and, in operation, generate a pre-determined temperature distribution across the substrate 325 in conjunction with the first pyrometer 356, the second pyrometer 358, and the controller 340. The chamber lid 306, the upper chamber liner 316, and the lower dome 332 may be formed from quartz as discussed above; however, other IR transparent and process compatible materials may also be used to form these components. The lamps 352, 354 may be part of a multi-zone lamp heating apparatus to provide thermal uniformity to the backside of the susceptor 100. For example, the heating system 351 may include a plurality of heating zones, where each heating zone includes a plurality of lamps. For example, the one or more lamps 352 may be a first heating zone and the one or more lamps 354 may be a second heating zone. The lamps 352, 354 may provide a wide thermal range of between about 200 to about 1300 degrees Celsius, for example from about 300 to about 700 degrees Celsius on the processing surface 323 of the substrate 325.

The lamps 352, 354 may provide a fast response control of about 0.1 to about 10 degrees Celsius per second on the processing surface 323 of the substrate 325, when disposed on the susceptor 100. In some embodiments, where the substrate 325 is supported, for example, by edge rings or by pins, the heating rates could be about 200 degrees Celsius per second on the processing surface 323. For example, the thermal range and fast response control of the lamps 352, 354 may provide deposition uniformity on the substrate 325. Further, the lower dome 332 may be temperature controlled, for example, by active cooling or window design, to further aid control of thermal uniformity on the backside of the susceptor 100, and/or on the processing surface 323 of the substrate 325.

The processing volume 301a may be formed or defined by a plurality of chamber components. For example, such chamber components may include one or more of the chamber lid 306, the spacer liner 313, the upper chamber liner 316, the lower chamber liner 331, and the susceptor 100. The processing volume 301a may include interior surfaces comprising quartz, such as the surfaces of any one or more of the chamber components that form the processing volume 301a. In some embodiments, other materials compatible with the processing environment may be used, such as silicon carbide (SiC) or SiC coated graphite for the susceptor 100. The processing volume 301a may accommodate any suitably sized substrate, for example, such as 200 mm, 300 mm, 450 mm, or the like. If the substrate 325 is about 300 mm, then the interior surfaces, for example, the upper and lower chamber liners 316, 331, may be about 50 mm to about 100 mm radially away from the edge of the substrate 325. In some embodiments, the processing surface 323 of the substrate 325 may be disposed at up to about 100 mm, for example, between about 20 mm to about 100 mm, vertically from the chamber lid 306.

The processing volume 301a may have a varying volume, for example, the size of the volume 301 may shrink when the lift mechanism 372 raises the susceptor 100 closer to the chamber lid 306 and expand when the lift mechanism 372 lowers the susceptor 100 away from the chamber lid 306. The processing volume 301a may be cooled by one or more active or passive cooling components. For example, the volume 301 may be passively cooled by the walls of the process chamber 310, which for example, may be stainless steel or the like. The volume 301 may be actively cooled, for example, by flowing a coolant gas or fluid about the process chamber 310.

The controller 340 may be coupled to various components of the process system 300 to control the operation thereof, for example, including the gas panel 308 and the actuator 330. The controller 340 includes a central processing unit (CPU) 342, a memory 344, and support circuits 346. The controller 340 may control the process chamber 310 and various components thereof, such as the actuator 330, directly (as shown in FIG. 3) or, alternatively, via computers (or controllers) associated with the process chamber 310. The controller 340 may be one of any form of general-purpose computer processor that can be used in an industrial setting for controlling various chambers and sub-processors. The memory, or computer readable medium, 344 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 346 are coupled to the CPU 342 for supporting the processor in a conventional manner. The support circuits 346 include cache, power supplies, clock circuits, input/output circuitry and subsystems, and the like. Inventive methods as described herein may be stored in the memory 344 as a software routine that may be executed or invoked to control the operation of the process system 300 in the manner described herein. The software routine may also be stored and/or executed by a second CPU (not shown) that is remotely located from the hardware being controlled by the CPU 342.

The above description is directed to a susceptor comprising one or more features on the second surface configured to reflect more incident energy than a portion of the second surface without the feature. However, the features may be included on any surface of the susceptor or other components within the process chamber for which temperature readings are desired.

While the foregoing is directed to embodiments of the present invention, other and further embodiments of the invention may be devised without departing from the basic scope thereof, and the scope thereof is determined by the claims that follow.

1. An apparatus for processing a substrate, comprising:
a susceptor having a first substrate supporting surface and a second surface oriented opposite the first surface; and
one or more reflective features formed on the second surface in an annular pattern, wherein the one or more reflective features are more reflective than the second surface of the susceptor.

2. The apparatus of claim 1, wherein the susceptor is formed from a material comprising graphite, silicon carbide, or combinations thereof.

3. The apparatus of claim 2, wherein the susceptor comprises silicon carbide coated graphite.

4. The apparatus of claim 1, wherein the one or more reflective features are conformally deposited on the second surface.

5. The apparatus of claim 1, wherein the one or more reflective features comprise a material selected from the group consisting of aluminum, platinum, iridium, rhenium, gold, and combinations thereof.

6. The apparatus of claim 1, wherein the one or more reflective features are coated with silicon dioxide.

7. The apparatus of claim 1, wherein the one or more reflective features are conformally deposited by physical vapor deposition.

8. The apparatus of claim 7, wherein the one or more reflective features comprise silicon dioxide coated aluminum.

9. The apparatus of claim 1, wherein a shape of the one or more reflective features exhibit a high aspect ratio oriented perpendicularly to a rotational path of the susceptor.

10. An apparatus for processing a substrate, comprising:
a susceptor having a first substrate supporting surface and a second surface oriented opposite the first surface; and
one or more reflective features formed on the second surface in an annular pattern, wherein the one or more reflective features are more reflective than the second surface of the susceptor and at least a portion of the second surface is exposed adjacent to the one or more reflective features.

11. The apparatus of claim 10, wherein the one or more reflective features comprise a continuous elliptical band.

12. The apparatus of claim 10, wherein the one or more reflective features comprise discrete structures arranged in an elliptical pattern.

13. The apparatus of claim 10, wherein a surface roughness of the one or more reflective features is similar to a surface roughness of the second surface.

14. The apparatus of claim 10, wherein a first annular pattern of the one or more reflective features is disposed at a first radius on the second surface and a second annular pattern of the one or more reflective features is disposed at a second radius on the second surface, and wherein the second radius is different from the first radius.

15. An apparatus for processing a substrate, comprising:
a process chamber having a processing volume;
a susceptor disposed in the processing volume, the susceptor having a first substrate supporting surface and a second surface oriented opposite the first surface;
one or more reflective features formed on the second surface in an annular pattern, wherein the one or more reflective features are more reflective than the second surface of the susceptor;
a plurality of radiant energy sources coupled to the chamber below the second surface; and
a temperature sensor oriented to detect electromagnetic radiation from a desired radius of the second surface.

16. The apparatus of claim 15, wherein the one or more reflective features are selected to reflect electromagnetic energy at a wavelength of between about 3.0 micrometers to about 3.6 micrometers.

17. The apparatus of claim 15, wherein the susceptor comprises monolithic silicon carbide, graphite coated with silicon carbide, or combinations thereof.

18. The apparatus of claim 15, wherein the one or more reflective features are conformally deposited on the second surface.

19. The apparatus of claim 15, wherein the one or more reflective features comprise a material selected from the group consisting of aluminum, platinum, iridium, rhenium, gold, and combinations thereof.

20. The apparatus of claim 15, wherein the one or more reflective features are coated with silicon dioxide.
